(19) United States
(12) Patent Application Publication
(10) Pub. No.: US 2026/0252147 A1
(43) Pub. Date: Aug. 27, 2026

(54) Display Device

(71) Applicant: LG Display Co., Ltd., Seoul (KR)

(72) Inventor: Minsan Jo, Paju-si (KR)

(21) Appl. No.: 19/423,853

(22) Filed: Dec. 17, 2025

(30) Foreign Application Priority Data
Feb. 25, 2025 (KR) 10-2025-0024547

(51) Int. Cl. G06F 1/16

(52) U.S. Cl. CPC G06F 1/1658; G06F 1/1686

(57) ABSTRACT

Embodiments of the present disclosure may provide a display device including a display module for displaying an image, a frame attached to the display module, a first attachment member for attaching the display module to the frame, and a buffer waterproof member disposed in a space between the frame and the display module and on at least a portion of the frame.

### CROSS REFERENCE TO RELATED APPLICATION

This application claims priority from Republic of Korea Patent Application No. 10-2025-0024547, filed on February 25, 2025, which is hereby incorporated by reference for all purposes as if fully set forth herein.

### TECHNICAL FIELD

Embodiments of the present disclosure relate to a data driving circuit and a display device.

### BACKGROUND

With the advent of the information age, the display field, which visually represents electrical information signals, has rapidly developed. In response, a variety of display devices with superior performance, such as thinness, weight reduction, and low power consumption, are being developed. Specific examples of these display devices include a liquid crystal display (LCD), a plasma display panel (PDP), a field emission display (FED), and an organic light-emitting diode (OLED) display.

A display device may incorporate a variety of components. Accordingly, diverse layout structures are being developed to protect these components.

### SUMMARY

Embodiments of the present disclosure may provide a display device capable of minimizing stress between a frame and a display module within a display device.

Embodiments of the present disclosure may provide a display device including a ventilation member that discharges air generated during the process of forming a buffer waterproof member to minimize stress generation.

The objects of the embodiments of the present disclosure are not limited to the objects described in this specification, and other objects will be clearly understood by those skilled in the art from the description below.

Embodiments of the present disclosure may provide a display device including a display module for displaying an image, a frame attached to the display module, a first attachment member for attaching the display module to the frame, and a buffer waterproof member disposed in a space between the frame and the display module and on at least a portion of the frame.

Embodiments of the present disclosure may provide a display device including a display module for displaying an image and including a camera module overlapping area, a frame attached to the display module, and a first attachment member for attaching the display module to the frame. The first attachment member may includes a first ventilation member and a second ventilation member. The first ventilation member and the second ventilation member may be respectively disposed in a first corner area and a second corner area of a first side where the camera module overlapping area overlaps with the first attachment member.

According to embodiments of the present disclosure, it is possible to provide a display device including a first attachment member for attaching a frame and a display module and including a ventilation member.

According to embodiments of the present disclosure, it is possible to provide a process-optimized display device by providing a buffer waterproof member in the required space using a mold to minimize stress.

The effects of the embodiments of the present disclosure are not limited to the effects described as above, and other effects will be clearly understood by those skilled in the art from the claims.

### BRIEF DESCRIPTION OF THE DRAWINGS

The present disclosure will be more fully understood from the detailed description and accompanying drawings provided below, which are provided for illustration purposes only and are not intended to limit the present disclosure.

FIG. 1 is a system configuration diagram of a display device according to embodiments of the present disclosure.

FIG. 2 is an exploded perspective view of a display device according to embodiments of the present disclosure.

FIG. 3 is a plan view of a combined display module and frame according to embodiments of the present disclosure.

FIG. 4 is a cross-sectional view taken along line A-A' of FIG. 3 according to embodiments of the present disclosure.

FIG. 5 is a plan view of a combined display module, frame, and mold according to embodiments of the present disclosure.

FIG. 6 is a cross-sectional view taken along line B-B' of FIG. 5 according to embodiments of the present disclosure.

FIG. 7 is a plan view of a combined display module, frame, and buffer waterproof member according to embodiments of the present disclosure.

FIG. 8 is a cross-sectional view taken along line C-C' of FIG. 7 according to embodiments of the present disclosure.

FIG. 9 is a cross-sectional view of a combined display module, frame, buffer waterproof member, and housing according to embodiments of the present disclosure.

FIG. 10 is a plan view of a first attachment member according to embodiments of the present disclosure.

FIG. 11 is a cross-sectional view illustrating a portion of a cross-section where a ventilation member is located within in a state in which a display module and a frame are combined according to embodiments of the present disclosure.

FIG. 12 is a cross-sectional view illustrating a portion of a cross-section where a ventilation member is located within in a state in which a display module, a frame, and a buffer waterproof member are combined according to embodiments of the present disclosure.

### DETAILED DESCRIPTION

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element may be included in at least one of two or more elements that "are connected or coupled to", “contact or overlap”, etc. each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, it will be described embodiments of the present disclosure in detail with reference to the accompanying drawings.

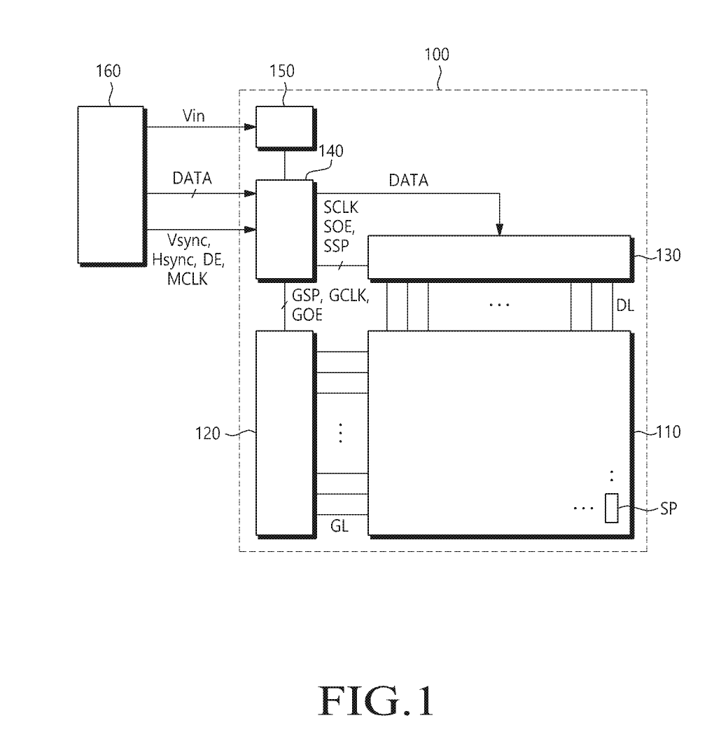

FIG. 1 is a system configuration diagram of a display device 100 according to embodiments of the present disclosure.

Referring to FIG. 1, a display device 100 according to embodiments of the present disclosure may include a display panel 110 in which a plurality of gate lines GL and data lines DL are connected and a plurality of sub-pixels SP are arranged in a matrix form, a gate driving circuit 120 for driving a plurality of gate lines GL, a data driving circuit 130 for supplying data voltage through a plurality of data lines DL, a controller 140 for controlling the gate driving circuit 120 and the data driving circuit 130, and a power management circuit 150.

The display panel 110 may display an image based on a scan signal transmitted from the gate driving circuit 120 through the plurality of gate lines GL and a data voltage transmitted from the data driving circuit 130 through the plurality of data lines DL.

In the case of a liquid crystal display, the display panel 110 may includes a liquid crystal layer formed between two substrates, and may be operated in any known mode, such as a TN (Twisted Nematic) mode, a VA (Vertical Alignment) mode, an IPS (In Plane Switching) mode, or a FFS (Fringe Field Switching) mode. In addition, in the case of an organic light-emitting display, the display panel 110 may be implemented in a top emission structure, a bottom emission structure, or a dual emission structure.

The display panel 110 may include a plurality of pixels arranged in a matrix form, and each pixel may be composed of sub-pixels SP of different colors, for example, a white sub-pixel, a red sub-pixel, a green sub-pixel, and a blue sub-pixel. In addition, each sub-pixel SP may be defined by a plurality of data lines DL and a plurality of gate lines GL.

One sub-pixel SP may include a thin film transistor (TFT) formed in an area where one data line DL and one gate line GL intersect, a light emitting device such as an organic light-emitting diode that charges a data voltage, and a storage capacitor that is electrically connected to the light emitting device to maintain the voltage.

The gate driving circuit 120 may be controlled by the controller 140, and may control the driving timing for a plurality of sub-pixels SP by sequentially outputting scan signals to a plurality of gate lines GL arranged on the display panel 110.

In this case, the gate driving circuit 120 may include one or more gate driving integrated circuits (GDIC), and may be located only on one side of the display panel 110 or on both sides of the display panel 110 depending on the driving method. Alternatively, the gate driving circuit 120 may be built into a bezel area of the display panel 110 and implemented in the form of a gate-in-panel (GIP).

The data driving circuit 130 may receive image data DATA from the controller 140 and convert the received image data DATA into an analog data voltage. The data driving circuit 130 may output the data voltage to each data line DL in accordance with the timing at which the scan signal is applied through the gate line GL, so that each sub-pixel SP connected to the data line DL emits the light of brightness corresponding to the data voltage.

Similarly, the data driving circuit 130 may include one or more source driving integrated circuits SDIC, and the source driving integrated circuits SDIC may be connected to bonding pads of the display panel 110 in a tape automated bonding (TAB) manner or a chip-on-glass (COG) manner or may be directly placed on the display panel 110.

The controller 140 may supply various control signals to the gate driving circuit 120 and the data driving circuit 130, and control the operation of the gate driving circuit 120 and the data driving circuit 130. That is, the controller 140 may control the gate driving circuit 120 to output a scan signal according to the timing implemented in each frame, and may transmit image data DATA received from the outside to the data driving circuit 130.

In this case, the controller 140 may receive various timing signals including a vertical synchronization signal Vsync, a horizontal synchronization signal Hsync, a data enable signal DE, and a main clock MCLK together with the image data DATA from an external host system 160.

The host system 160 may be any one of a TV system, a set-top box, a navigation system, a personal computer (PC), a home theater system, a mobile device, and a wearable device.

Accordingly, the controller 140 may generate a control signal using various timing signals received from the host system 160, and transmit the control signal to the gate driving circuit 120 and the data driving circuit 130.

For example, the controller 140 may output various gate control signals including a gate start pulse GSP, a gate clock GCLK, and a gate output enable signal GOE in order to control the gate driving circuit 120.

In addition, the controller 140 may output various data control signals including a source start pulse SSP, a source clock SCLK, and a source output enable signal SOE in order to control the data driving circuit 130.

The display device 100 may include a power management circuit 150 that supplies various voltages or currents to the display panel 110, the gate driving circuit 120, the data driving circuit 130, or controls various voltages or currents to be supplied.

The power management circuit 150 may adjust the DC input voltage Vin supplied from the host system 160 to generate power necessary for driving the display panel 110, the gate driving circuit 120, and the data driving circuit 130.

The display device 100 may be various types of devices such as a liquid crystal display, an organic light emitting display, and a plasma display panel.

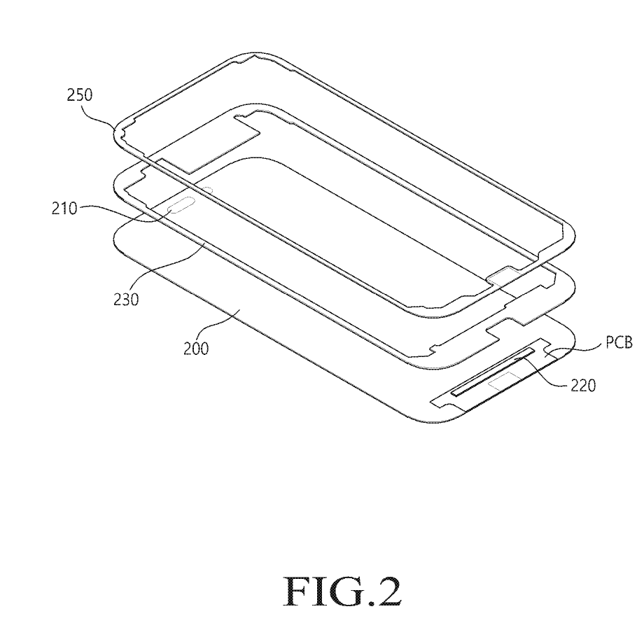

FIG. 2 is an exploded perspective view of a display device 100 according to embodiments of the present disclosure.

Referring to FIG. 2, the display device 100 may include a display module 200, a frame 230, and a buffer waterproof member 250.

The display module 200 may include a printed circuit board (PCB), a circuit block 220, and a camera module overlapping area 210. The circuit block 220 may be at least one of a data driving circuit 130, a controller 140, and a power management circuit 150. The circuit block 220 may be covered by a shielding tape. As the circuit block 220 is covered by the shielding tape, the circuit block 220 may be protected from external electromagnetic interference.

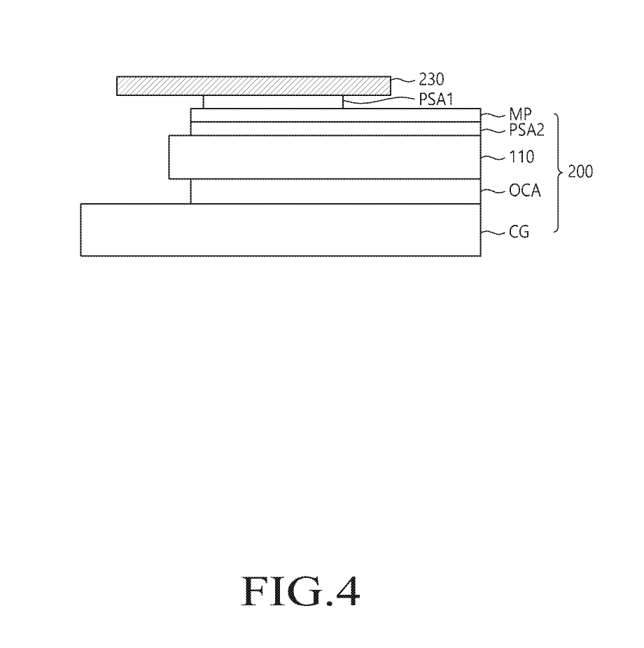

The frame 230 may be coupled to the display module 200. As the frame 230 is coupled to the display module 200, the display module 200 may be protected. For example, a first attachment member may be positioned between the display module 200 and the frame 230. For example, the display module 200 and the frame 230 may be attached by an adhesive material of the first attachment member. A detailed description thereof may be provided in the description below with referece to FIG. 4.

The buffer waterproof member 250 may be positioned in a space between the frame 230 and the display module 200 and on at least a portion of the frame 230.

For example, the buffer waterproof member 250 may be positioned on at least a portion of the upper surface of the frame 230, at least a portion of the lower surface of the frame 230, and on a side surface of the frame 230. The buffer waterproof member 250 may be positioned in the space between the frame 230 and the display module 200. Accordingly, stress generated due to the space between the frame 230 and the display module 200 may be minimized. If the stress generated is minimized, the bending phenomenon of the display device 100 can be minimized.

Furthermore, if the buffer waterproof member 250 is positioned in the space between the display module 200 and the frame 230, it is possible to minimize the exposure of internal components of the display device 100 to moisture, thereby enhancing the waterproofing function of the display device 100.

Hereinafter, it will be described the process of combining the display module 200, the frame 230, and the buffer waterproof member 250.

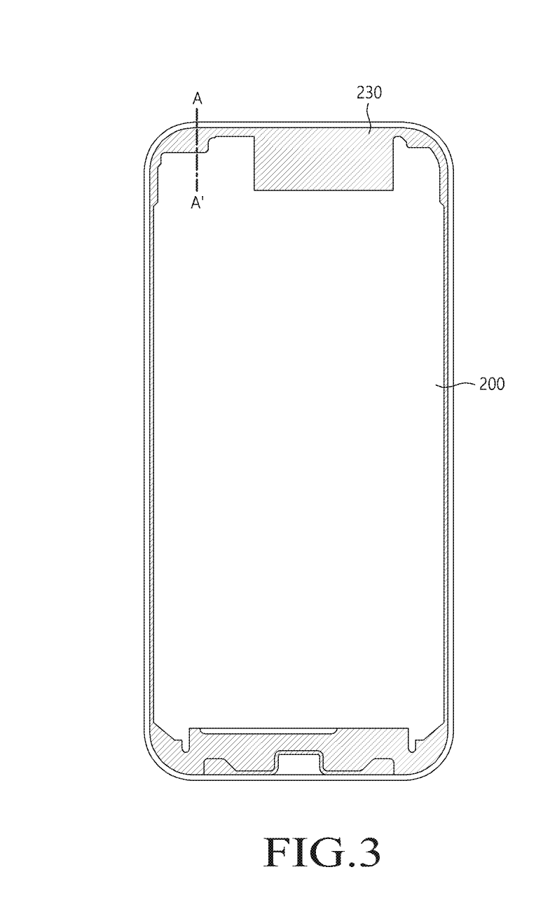

FIG. 3 is a plan view of a combined display module 200 and frame 230 according to embodiments of the present disclosure.

Referring to FIG. 3, the display module 200 and the frame 230 may be attached by the adhesive component of the first attachment member. The frame 230 may have a shape that defines the periphery of the display module 200. Accordingly, the frame 230 can protect against external forces acting from the periphery of the display module 200. In addition, the frame 230 may overlap with the upper surface of the camera module overlapping area 210 of the display module 200 and an area where the circuit block 220 is located. Accordingly, it is possible to protect the camera module overlapping area 210 and the circuit block 220.

A description of the first attachment member may be exemplified in the description below of FIG. 4.

FIG. 4 is a cross-sectional view taken along line A-A’ of FIG. 3 according to embodiments of the present disclosure.

Referring to FIG. 4, the display device 100 may include a display module 200, a first attachment member PSA1, and a frame 230. The display module 200 may include a cover glass CG, an optical adhesive OCA, a display panel 110, a second attachment member PSA2, and a metal plate MP.

For example, the cover glass CG may protect the display panel 110. For example, the cover glass CG may be a component that receives touch input.

For example, the optical adhesive OCA may attach the cover glass CG and the display panel 110. For example, the optical adhesive OCA may include a transparent component. For example, the optical adhesive OCA may be configured so that the optical output of the display panel 110 is not distorted.

The description of the display panel 110 may overlap with the description in FIG. 1, and therefore will be omitted.

For example, the second attachment member PSA2 may attach the display panel 110 and the metal plate MP.

For example, the metal plate MP may assist in the rigidity of the display panel 110.

For example, the first attachment member PSA1 may attach the metal plate MP and the frame 230. Alternatively, the display module 200 and the frame 230 may be attached.

The display device 100 may further include a buffer waterproof member 250. Hereinafer, a process for forming the buffer waterproof member 250 will be described.

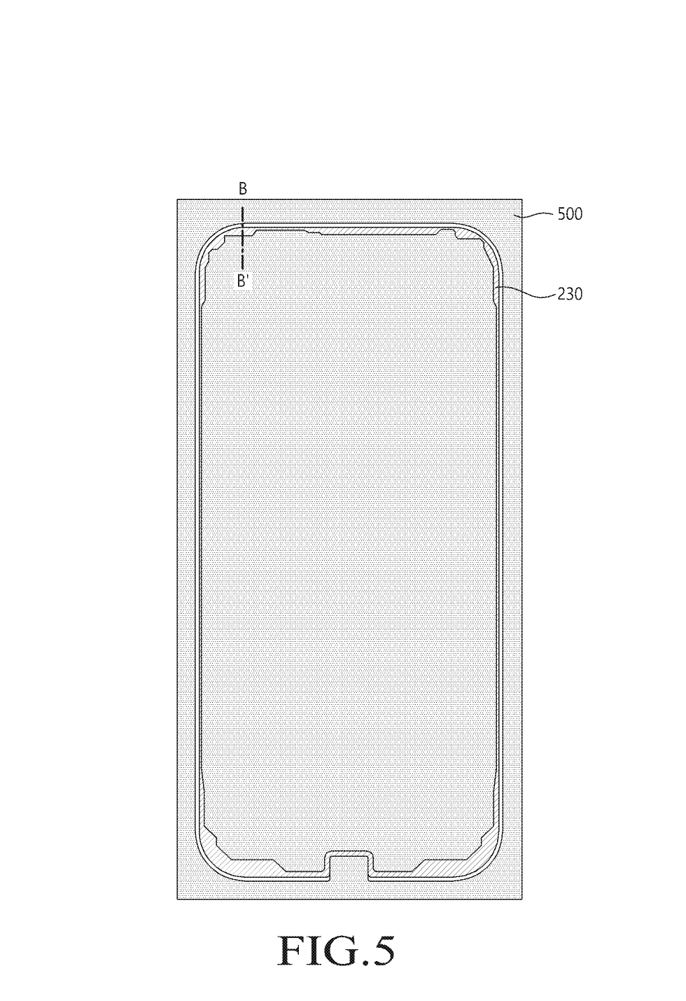

FIG. 5 is a plan view illustrating a display module 200, a frame 230, and a mold 500 coupled together according to embodiments of the present disclosure.

Referring to FIG. 5, the mold 500 may be coupled to the display device 100 to form a buffer waterproof member 250 within the display device 100.

For example, the mold 500 may guide a path along which the buffer waterproof member 250 is formed.

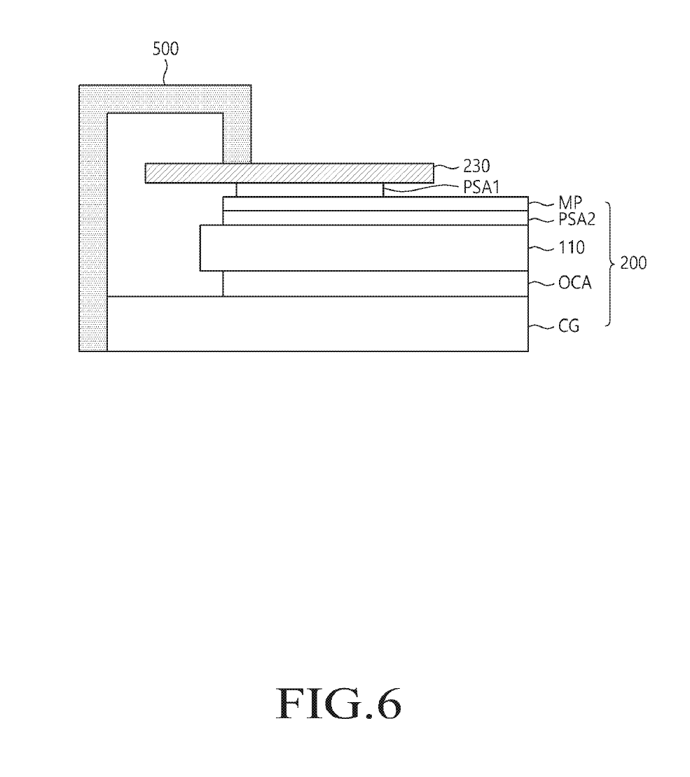

FIG. 6 is a cross-sectional view taken along line B-B' of FIG. 5 according to embodiments of the present disclosure.

There will be omitted the descriptions in FIG. 6 overlapping with the description of FIG. 4.

Referring to FIG. 6, the mold 500 may be disposed on the frame 230. Additionally, the mold may be disposed on the side of the cover glass CG. At least a portion of the mold 500 may be in contact with the frame 230, and at least another portion of the mold 500 may be spaced apart from the frame 230.

For example, the mold 500 may form a space in which the buffer waterproof member 250 is formed. For example, the space in which the buffer waterproof member 250 is formed may be referred to as a space in which the mold 500 and the frame 230 are spaced apart, and a space in which the mold 500 and the display module 200 are spaced apart. For example, the buffer waterproof member 250 may be formed by injecting a resin component into a space formed by the mold 500. Accordingly, the buffer waterproof member 250 may be formed in a predetermined shape, thereby preventing the bending or optical distortion of the display device 100.

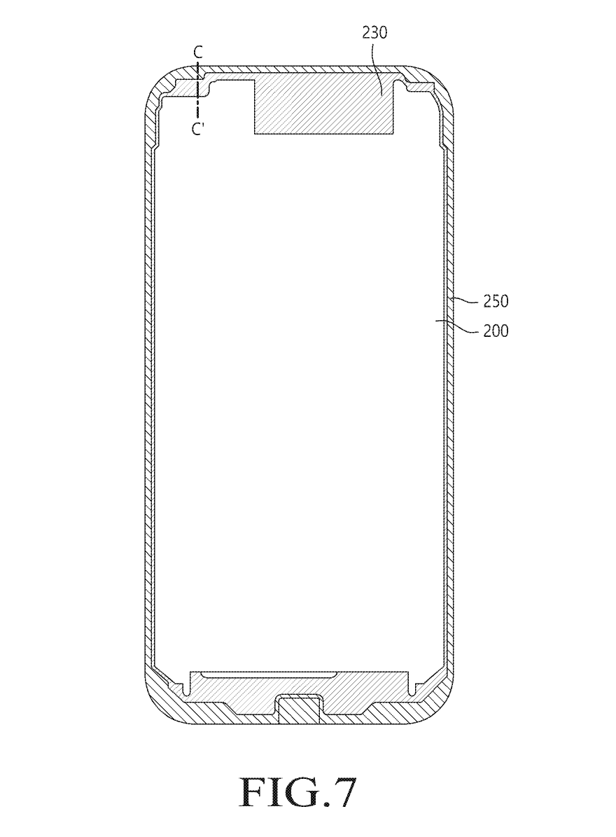

FIG. 7 is a plan view illustrating a combined display module 200, frame 230, and buffer waterproof member 250 according to embodiments of the present disclosure.

Referring to FIG. 7, the display device 100 may include a display module 200, a frame 230, and a buffer waterproof member 250.

FIG. 7 may be a plan view of the display device 100 in which the buffer waterproof member 250 is formed in the space formed by the mold 500 in FIG. 6 and then the mold 500 is separated.

For example, the buffer waterproof member 250 may not overlap with the camera module overlapping area 210, at least a portion of the printed circuit board (PCB), and the circuit block 220.

Accordingly, heat generated in the camera module overlapping area 210, the printed circuit board (PCB), and the circuit block 220 may be dissipated through the frame 230. That is, the buffer waterproof member 250 may not impede the dissipation of heat.

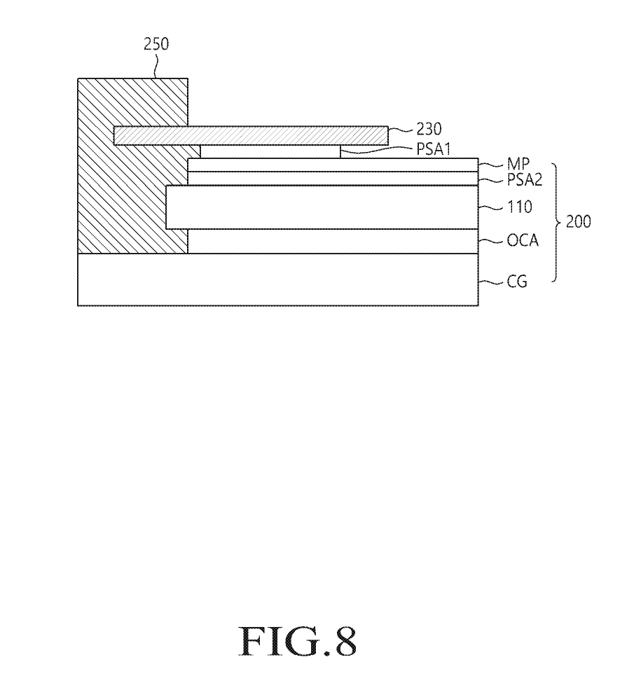

FIG. 8 is a cross-sectional view taken along line C-C’ of FIG. 7 according to embodiments of the present disclosure.

In the description of FIG. 8, descriptions that overlap with those in FIG. 4 and FIG. 6 will be omitted.

Referring to FIG. 8, the buffer waterproof member 250 may be disposed in a space between the display module 200 and the frame 230 and on the side surfaces of the display module 200 and the frame 230.

Accordingly, stress due to the step between the display module 200 and the frame 230 can be minimized. In addition, it is possible to prevent dust or moisture from penetrating from the outside.

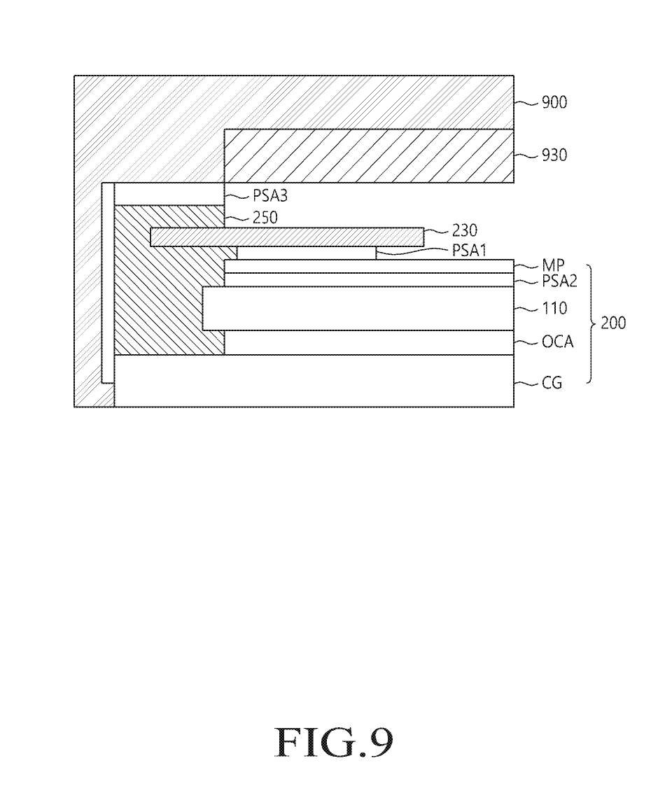

FIG. 9 is a cross-sectional view of a combined display module 200, frame 230, buffer waterproof member 250, and housing 900 according to embodiments of the present disclosure.

Referring to FIG. 9, the display device 100 may include a display module 200, a frame 230, a buffer waterproof member 250, a third attachment member PSA3, a housing 900, and a function module 930.

In the description of FIG. 9, the description that overlaps with the descriptions in FIGS. 4, 6, and 8, may be omitted.

For example, the third attachment member PSA3 may attach the buffer waterproof member 250 and the housing 900.

The housing 900 may be disposed at the outermost portion of the display device 100. The housing 900 may protect the display module 200, the frame 230, the buffer waterproof member 250, and the function module 930. For example, the housing 900 may be disposed to surround the side and upper surface of the buffer waterproof member 250.

Accordingly, the buffer waterproof member 250 is disposed within the display device 100, so that it is possible to prevent the foreign substances (e.g., moisture or dust) not blocked by the housing 900 from the outside from penetrating the display module 200 or the frame 230.

The function module 930 may include at least one of a camera module and a battery.

While the buffer waterproof member 250 is disposed, air present in the space where the buffer waterproof member 250 is disposed may not be released or discharged to the outside of the display device 100. Accordingly, there may be formed air bubbles within the display device 100.

To prevent the formation of the air bubbles, the first attachment member PSA1 may be provided with a ventilation member that discharges air generated within the space between the frame 230 and the display module 200. Alternatively, the first attachment member PSA1 may be provided with a ventilation member that discharges air generated within the space between the frame 230, the display module 200, and the mold 500.

Hereinafter, ventilation members within the first attachment member PSA1 will be described.

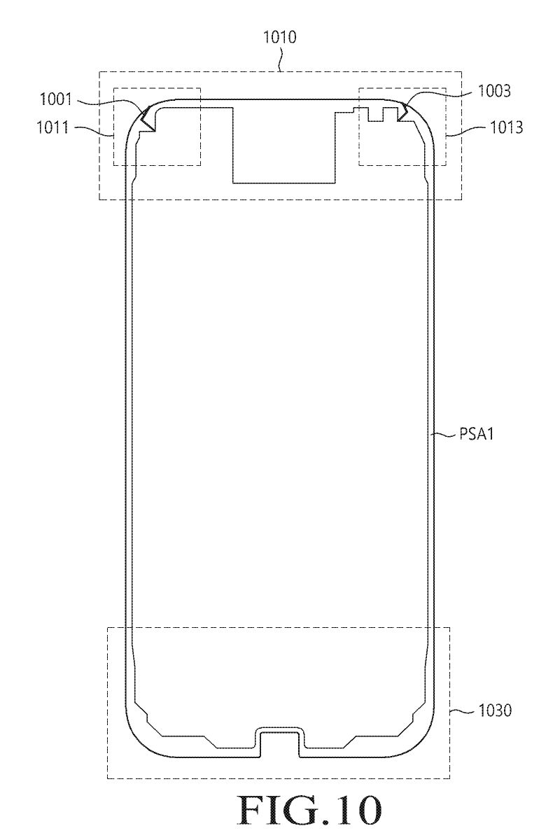

FIG. 10 is a plan view illustrating the first attachment member PSA1 according to embodiments of the present disclosure.

Referring to FIG. 10, the first attachment member PSA1 may include a first ventilation member 1001 and a second ventilation member 1003.

For example, the first attachment member PSA1 may include a first side 1010 that overlaps with a camera module overlapping area 210 within the display module 200, and a second side 1030 that overlaps with a circuit block 220 within the display module 200.

For example, the first side 1010 may include a first corner area 1011 and a second corner area 1013.

For example, the first ventilation member 1001 may be disposed in the first corner area 1011. For example, the second ventilation member 1003 may be disposed in the second corner area 1013. Accordingly, air formed on the left side of the display device 100 may be discharged through the first ventilation member 1001, and air formed on the right side of the display device 100 may be discharged through the second ventilation member 1003. Left and right may be relative concepts.

For example, the first ventilation member 1001 and the second ventilation member 1003 may be formed in a shape of a strict inequality sign, for example, a > shape, a < shape. However, embodiments of the present disclosure is not limited thereto, and the first ventilation member 1001 and the second ventilation member 1003 may be formed in various shapes, such as an arrow shape, a triangle shape, a V shape, an I shape, a hook shape, a bent shape, and a pointer shape.

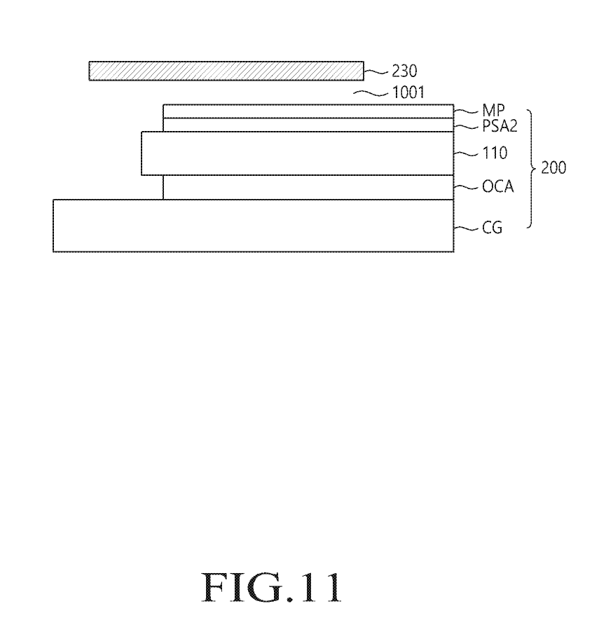

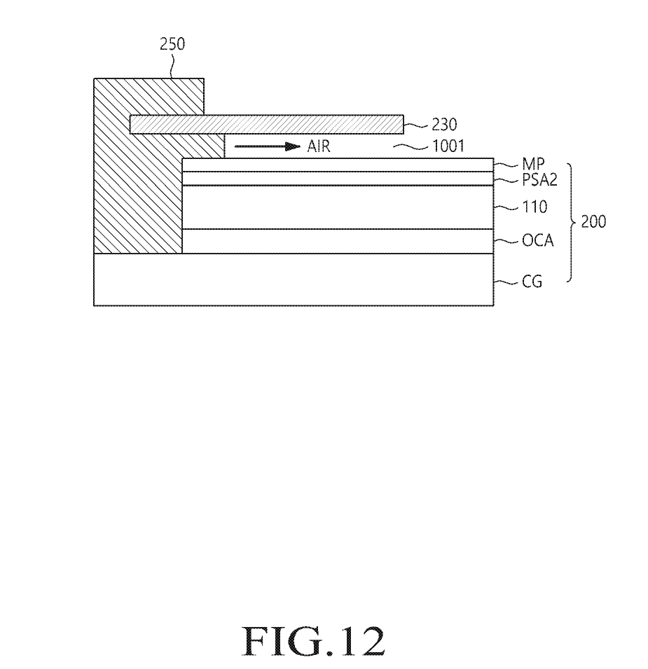

FIG. 11 is a cross-sectional view illustrating a part of a cross-section where a ventilation member is located in a state where a display module 200 and a frame 230 are combined according to embodiments of the present disclosure, and FIG. 12 is a cross-sectional view illustrating a part of a cross-section where a ventilation member is located in a state where a display module 200, a frame 230, and a buffer waterproof member 250 are combined according to embodiments of the present disclosure.

In the description of FIGS. 11 and 12, descriptions that overlap with those in FIGS. 4, 6, 8, and 9, may be omitted.

Referring to FIG. 11, the first attachment member PSA1 may not be disposed between the display module 200 and the frame 230 within an area where a ventilation member (e.g., the first ventilation member 1001 and the second ventilation member 1003) is located.

That is, the first ventilation member 1001 and the second ventilation member 1003 may be formed by removing at least a portion of the first attachment member PSA1. For example, the first ventilation member 1001 and the second ventilation member 1003 may be formed by removing the first attachment member PSA1 disposed in the first corner area 1011 and the second corner area 1013 of the first side 1010, respectively, where the camera module overlapping area 210 and the first attachment member PSA1 overlap with each other.

Referring to FIG. 12, since the buffer waterproof member 250 is formed, the moving air AIR can be released into the space where the first attachment member PSA1 is not disposed.

Accordingly, it is possible to prevent the air bubbles from being visible to the outside after all components of the display device 100 are fastened.

The display device according to embodiments of the present disclosure may be described as follows.

A display device may include a display module for displaying an image, a frame attached to the display module, a first attachment member for attaching the display module to the frame, and a buffer waterproof member disposed in a space between the frame and the display module and on at least a portion of the frame.

The first attachment member may include at least one ventilation member for discharging air generated within the space between the frame and the display module.

The display module may include a camera module overlapping area, a printed circuit board, and a circuit block disposed on the printed circuit board.

The buffer waterproof member may not overlap with the camera module overlapping area, at least a portion of the printed circuit board, and the circuit block.

The first attachment member may include a first ventilation member and a second ventilation member.

The first ventilation member and the second ventilation member may be disposed in a first corner area and a second corner area of a first side where the camera module overlapping area and the first attachment member overlap, respectively.

The first ventilation member and the second ventilation member may be formed by removing the first attachment member, which is respectively disposed in the first corner area and the second corner area of the first side where the camera module overlapping area and the first attachment member overlap.

The first ventilation member and the second ventilation member may be formed in a shape of a strict inequality sign.

The circuit block may include at least one of a controller, a data driving circuit, and a power management circuit.

The display device may further include a housing disposned to surround the side surface and the upper surface of the buffer waterproof member.

The buffer waterproof member may include a resin component.

The display device may include a display module for displaying an image and including a camera module overlapping area, a frame attached to the display module, and a first attachment member attaching the display module and the frame.

The first attachment member may include a first ventilation member and a second ventilation member.

The first ventilation member and the second ventilation member may be respectively disposed in a first corner area and a second corner area of a first side where the camera module overlapping area and the first attachment member overlap.

The first ventilation member and the second ventilation member may be formed by removing the first attachment member respectively positioned in the first corner area and the second corner area of the first side where the camera module overlapping area and the first attachment member overlap.

The first ventilation member and the second ventilation member may be formed in a shape of a strict inequality sign.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

What is claimed is:

1. A display device comprising:
a display module for displaying an image;
a frame attached to the display module;
a first attachment member for attaching the display module to the frame; and
a buffer waterproof member disposed in a space between the frame and the display module and on at least a portion of the frame.

2. The display device of claim 1, wherein at least one ventilation member is disposed in the first attachment member to discharge air generated within the space between the frame and the display module.

3. The display device of claim 1, wherein the display module includes a camera module overlapping area, a printed circuit board, and a circuit block disposed on the printed circuit board.

4. The display device of claim 3, wherein the buffer waterproof member does not overlap with the camera module overlapping area, at least a portion of the printed circuit board, and the circuit block.

5. The display device of claim 4, wherein the first attachment member includes a first ventilation member and a second ventilation member,
wherein the first ventilation member and the second ventilation member are respectively disposed in a first corner area and a second corner area of a first side where the camera module overlapping area overlaps with the first attachment member.

6. The display device of claim 5, wherein the first ventilation member and the second ventilation member are formed by removing the first attachment member, which is respectively disposed in the first corner area and the second corner area of the first side where the camera module overlapping area overlaps with the first attachment member.

7. The display device of claim 6, wherein the first ventilation member and the second ventilation member are formed in a shape of a strict inequality sign.

8. The display device of claim 4, wherein the circuit block includes at least one of a controller, a data driving circuit, and a power management circuit.

9. The display device of claim 1, further comprising a housing disposed to surround a side surface of the buffer waterproof member and an upper surface of the buffer waterproof member.

10. The display device of claim 1, wherein the buffer waterproof member includes a resin component.

11. A display device comprising:
a display module for displaying an image and including a camera module overlapping area;
a frame attached to the display module; and
a first attachment member for attaching the display module to the frame,
wherein the first attachment member includes a first ventilation member and a second ventilation member,
wherein the first ventilation member and the second ventilation member are respectively disposed in a first corner area and a second corner area of a first side where the camera module overlapping area overlaps with the first attachment member.

12. The display device of claim 11, wherein the first ventilation member and the second ventilation member are formed by removing the first attachment member, which is respectively disposed in the first corner area and the second corner area of the first side where the camera module overlapping area overlaps with the first attachment member.

13. The display device of claim 12, wherein the first ventilation member and the second ventilation member are formed in a shape of a strict inequality sign.
